(19) United States
(12) Patent Application Publication
(10) Pub. No.: US 2024/0210579 A1
(43) Pub. Date: Jun. 27, 2024

(54) LARGE-AREA SEMICONDUCTOR DRIFT DETECTOR FOR RADIATION DETECTION

(71) Applicants: Sahar ADNANI, Waterloo (CA); Karim S. Karim, Waterloo (CA)

(72) Inventors: Sahar ADNANI, Waterloo (CA); Karim S. Karim, Waterloo (CA)

(21) Appl. No.: 18/545,348

(22) Filed: Dec. 19, 2023

Related U.S. Application Data
(60) Provisional application No. 63/434,610, filed on Dec. 22, 2022.

(51) Int. Cl. G01T 1/24; H01L 27/146

(52) U.S. Cl. CPC G01T 1/24; H01L 27/14659

(57) ABSTRACT

The disclosure is directed at a large-area semiconductor drift detector that includes a set a substrate layer; a semiconductor layer; a set of drift microstrips positioned between the substrate layer and the semiconductor layer; and a set of collecting electrodes positioned between the substrate layer and the semiconductor layer and in a different plane than the set of drift microstrips; wherein the set of drift microstrips shape an electric field and direct charges within the drift detector towards the set of collecting electrodes.

### CROSS-REFERENCE TO OTHER APPLICATIONS

The disclosure claims priority from U.S. Provisional Application No. 63/434,610 filed Dec. 22, 2022, which is hereby incorporated by reference.

### FIELD

The disclosure is generally directed at the field of radiation detection and, more specifically, at a large-area semiconductor drift detector for radiation detection.

### BACKGROUND

Semiconductor drift detectors have been around since 1983 with their introduction for particle tracking. Employing microstrip detectors for this application was complicated due to the need for a large number of readout channels to achieve high spatial resolution.

The first structure proposed was a silicon drift detector (SDD) that included a single readout channel. An example of a prior art SDD 100 is illustrated in FIG. 1. The drifting field for the SDD was created, or generated, by applying a linear potential to strip arrays located on both sides of the detector. In this one-dimensional (1D) position-sensitive device or detector, the location where impingement between an electric field and the silicon layer occurred was determined by recording the drift time of carriers. In later embodiments, different structures were developed to realize two-dimensional (2D) position sensitivity, such as via the segmentation of the readout electrode in microstrip drift detectors and the segmentation of the back-plane electrode in cylindrical drift detectors. SDDs are mainly used to precisely resolve low-energy X-ray lines due to their high count rate and high energy resolution. The detection area in the SDD is significantly larger than the readout electrode, resulting in very low capacitance and lower electronic noise. This allows a shorter peaking time while maintaining high-energy resolution to increase the hitting capacity. However, silicon has a low detection efficiency for energies above 20 kev, so high-Z materials were combined with drift detector structures to achieve high detection efficiency, high energy resolution, and high count rate. A simple drift strip detector for cadmium zinc telluride (CZT) is shown in FIG. 2.

As shown in FIG. 2, the structure for drift strip detector 200 includes multiple cells with drift strips positioned between collecting electrodes on one side of the CZT layer and a planar electrode on the other side. Some embodiments included segmented planar electrodes orthogonal to the direction of the drift strips to realize position sensitivity along the strips.

Other higher-Z materials can be used to overcome the detection efficiency of SDDs The materials are direct converters of X-ray into electronic charge and deposited using conventional cost effective large area deposition processes such as evaporation or spray coating. The direct conversion nature of these materials makes them exhibit a high spatial resolution for large-area applications. However, many of these semiconductors suffer from low electron mobility, which degrades charge collection efficiency, energy resolution, and count rate capacity. To solve these issues, different techniques have been implemented to reduce or minimize the effect of slow charge carrier, such as employing unipolar charge sensing by embedded Frisch grids.

Therefore, there is provided a novel large-area semiconductor drift detector for radiation detection that overcomes some disadvantages in current solutions.

### SUMMARY

The disclosure is directed at a large-area semiconductor drift detector for radiation detection. In one embodiment, the disclosure is directed at an amorphous selenium (a-Se) drift detector structure. Advantages of the disclosure include, but are not limited to, reducing the sensitivity of collecting electrodes to slower charge carriers by leveraging the unipolar charge sensing; increasing the detection area ratio to the collecting electrode area and lowering the electronics noise. In order to achieve three-dimensional (3D) position sensing in the drift detector of the disclosure and to prevent or reduce the electronics complexity, the disclosure employs a readout circuit design based on a resistive charge division methodology. In charge division readout, the charge induced by an absorbed photon is divided along with the resistive layer or strip depending on the photon absorption location, and the charge is collected from both ends. One advantage of the disclosure is that the energy level of radiation, position of impingement of radiation and the timing of impingement of radiation may all be collected at the same time. In one aspect of the disclosure there is provided a large-area semiconductor drift detector including a substrate layer; a semiconductor layer; a set of drift microstrips positioned between the substrate layer and the semiconductor layer; and a set of collecting electrodes positioned between the substrate layer and the semiconductor layer and in a different plane than the set of drift microstrips; wherein the set of drift microstrips shape an electric field and direct charges within the drift detector towards the set of collecting electrodes.

In another aspect, the drift detector further includes a top planar electrode located on a side of the semiconductor layer opposite the set of drift microstrips and the set of collecting electrodes. In yet another aspect, the drift detector further includes a top set of drift microstrips located on a side of the semiconductor layer opposite the set of drift microstrips and the set of collecting electrode. In a further aspect, the top set of drift microstrips includes a set of wide width drift microstrips; and a set of narrow width drift microstrips. In another aspect, the set of drift microstrips and the set of collecting microstrips are staggered with respect to each other in a vertical plane. In yet another aspect, a width of each of the set of drift microstrips is a same as a width of each of the set of collecting electrodes. In an aspect, the set of wide width drift microstrips are in a same vertical plane as each of set of collecting electrodes. In another aspect, a width of each of the set of wide width drift microstrips is larger than a width of each of the set of collecting electrodes.

In yet another aspect, a width of each of the set of narrow width drift microstrips is a same as a width of each of the set of collecting electrodes. In another aspect, the semiconductor layer includes amorphous selenium; lead-based organic perovskites, bismuth-based organic perovskites, lead oxide, bismuth iodide, mercuric iodide, quantum dot based semiconductors, thallium bromide and amorphous silicon. In another aspect, the set of collecting electrodes are a set of dual readout resistive electrodes or a set of single readout metal collecting electrodes

In another aspect of the disclosure, there is provided a method of large-area semiconductor drift detector operation including receiving at least one of face-on or edge-on illumination; directing, via a set of drift microstrips, electron and hole charges towards a set of collecting electrodes; and determining a position of impingement of illumination against the drift detector; wherein the set of drift microstrips and the set of collecting electrodes are in different planes with respect to each other.

### BRIEF DESCRIPTION OF THE DRAWINGS

Some embodiments of the present disclosure are illustrated as an example and are not limited by the figures of the accompanying drawings, in which like references may indicate similar elements and in which:

FIG. 1 is a perspective view of a prior art silicon drift detector;

FIG. 2 is a front view of a prior art CZT drift strip detector;

FIG. 3 is a front view of a first embodiment of a large area semiconductor drift detector for radiation detection;

FIG. 4 is a front view of a second embodiment of a large area semiconductor drift detector for radiation detection;

FIG. 5 is a graph showing an electric field and potential for a cross section of the drift detector with planar top contact;

FIG. 6 is a graph showing an electric field and potential for a cross-section of the drift detector with parallel microstrips on both sides;

FIG. 7 is a graph showing an electric field magnitude and direction inside the detector with top contact voltage of 700V;

FIG. 8 is a graph showing electric field magnitude along the detector width in the middle of a-Se and perpendicular to the direction of strips for different values of top contacts

FIG. 9a is a graph showing an electric field streamline for VB=400 V;

FIG. 9b is a graph showing an electric field streamline for VB=1200 V;

FIG. 10 is an illustration of the weighting potential across the drift detector with collecting electrodes biased at 1V and other at zero;

FIG. 11a is a photograph of an embodiment of the disclosure fabricated on glass;

FIG. 11b is a photograph of an embodiment of the disclosure fabricated on a PET substrate;

FIG. 12a is a photograph of an experimental setup for a model;

FIG. 12b is a photograph of an experimental setup on motorized stages;

FIG. 13a is a graph showing photocurrents read from the two ends of a single electrode after dark current correction versus the position of the light source;

FIG. 13b is a graph showing detected position from the charge division equation along the electrode versus the physical location of the light source; and

FIG. 14 is a flowchart showing a method of large area semiconductor drift detector for radiation detection operation.

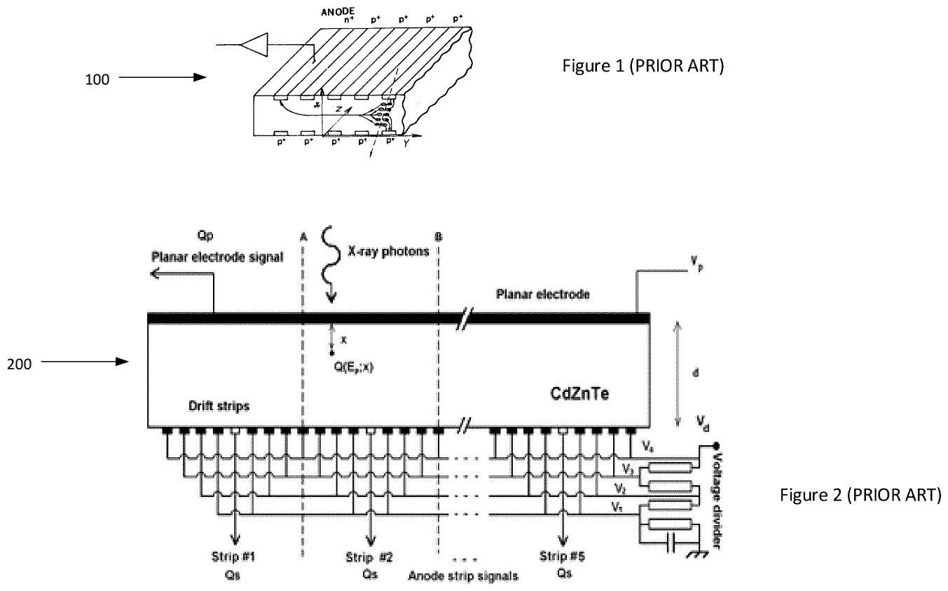

### DETAILED DESCRIPTION OF THE EMBODIMENTS

The disclosure is directed at a large-area semiconductor drift detector for radiation detection. In one embodiment, the disclosure is directed at an amorphous selenium (a-Se) drift detector structure.

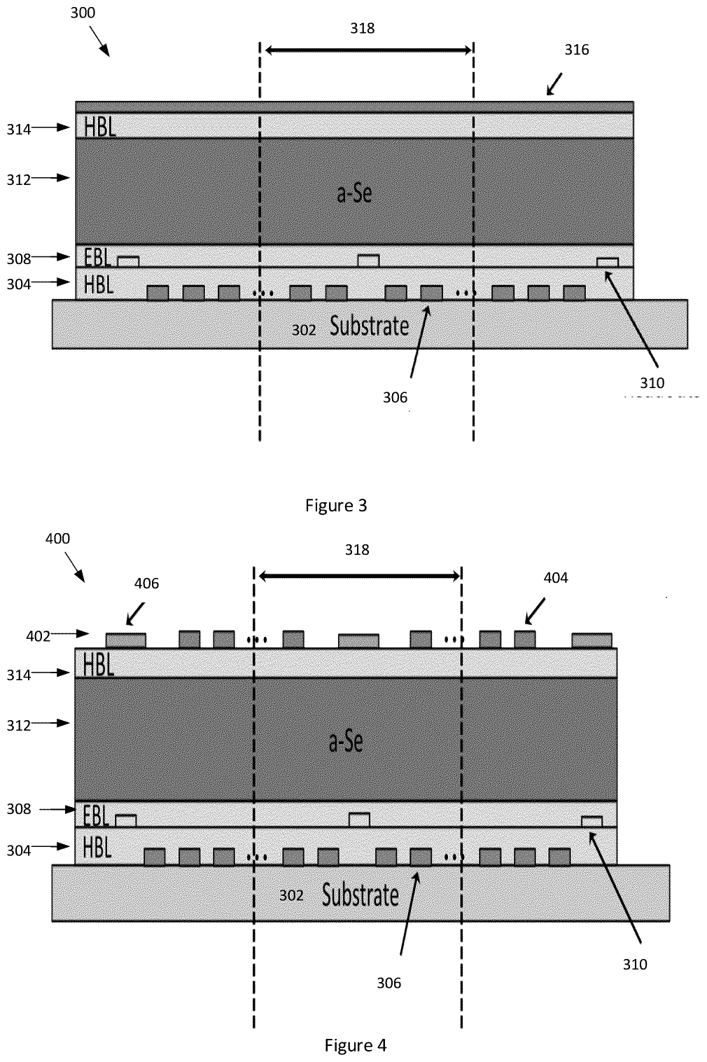

Turning to FIG. 3, a side view of one embodiment of a large-area semiconductor drift detector is shown. In one embodiment, the large-area semiconductor drift detectors of the disclosure (FIGS. 3 and 4) may be used to achieve a uniform drifting field potential with three-dimensional (3D) position sensing. The embodiment of FIG. 3 may be seen as a high voltage planar top electrode embodiment.

In the embodiment of FIG. 3, the drift detector 300 includes a substrate layer 302 that includes a first hole blocking layer/insulator (HBL) 304 (including a first set of drift microstrips 306) atop the substrate layer 302 and an electron blocking layer (EBL) 308 (including a set of charge collecting electrodes 310) atop the HBL 304. In the current embodiment, the drift microstrips 306 and the set of collecting electrodes 310 are in different planes with respect to each other. A semiconductor layer 312, such as one made from amorphous selenium (a-Se), is sandwiched between the EBL 308 and a second HBL 314. A planar top electrode 316 is located atop the second HBL 314. The planar top electrode 316 may be a high voltage planar top electrode. FIG. 3 also includes a pair of dotted lines which may represent or define an individual detector cell 318 within the drift detector 300.

In some embodiments, the semiconductor layer 312 can be made from or fabricated out of organic and inorganic materials thereby producing a large-area radiation sensitive semiconductor layer 312. Examples of other materials for the semiconductor layer 312 include, but are not limited to, lead and bismuth-based organic perovskites, lead oxide, bismuth iodide, mercuric iodide, quantum dot based semiconductors, thallium bromide and amorphous silicon.

In one embodiment, the drift microstrips 306 are placed or positioned atop the substrate layer 302 followed by the deposition of an insulating layer where the collecting electrodes 310 are placed or positioned within an insulating layer plane. The semiconducting layer 312 (which may include blocking layers for higher performance) is deposited and sits atop the insulating layer. Separating the planes of the drift microstrips 306 and the collecting electrodes 310 provides a benefit when with large-area semiconductors such as, but not limited to, a-Se, Pbl and/or quantum dots, to minimize or reduce leakage currents into the semiconductor layer 312 due to large voltages on the drift microstrips 306 and also unwanted charge trapping within the semiconductor layer 312.

Depending on the application or desired use of the drift detector 300, the charge collecting electrodes 310 may be a resistive electrode or a metal electrode with single or dual readouts. In one embodiment, the set of charge collecting electrodes 310 are dual readout electrodes which enable signals to be read out from either end of the collecting electrode 310 and then transmitted to a readout circuit (not shown). In one embodiment, if the drift detector 300 is being used for 3D position sensing, the dual end readouts 310 may be resistive collection electrodes. In another embodiment, if the drift detector 300 is being used for 1D or 2D position sensing, the dual end readouts 310 may be non-resistive collecting electrodes, such as ones fabricated by a metal such as, but not limited to, aluminum (Al) or copper (Cu). Use of resistive collecting electrodes simplifies the readout circuit while providing extra location details along the microstrip axis.

In other embodiments, the first HBL 304 may be an insulating layer, such as, but not limited to, silicon nitride. In other embodiments, the first HBL 304 and the EBL 308 may be a single insulating layer such as one fabricated from polyimide (PI) with both the first set of drift microstrips 306 and the set of charge collecting electrodes 310 located within the single insulating layer. Although shown as being in different planes and different layers in FIG. 3, the first set of drift microstrips 306 and the set of charge collecting electrodes 310 may be located within a same plane in the insulating layer or may be located on different planes with respect to each other within the single insulating layer. In embodiments where the drift microstrips 306 and the set of charge collecting electrodes 310 are in different planes within a single layer (insulating, hole blocking or electron blocking), one or both of the drift microstrips and the set of collecting electrodes may be embedded within the single layer. In further embodiments, the set of collecting electrodes may be embedded or positioned within the semiconductor layer.

In another embodiment, the second HBL 314 may include charge collecting electrodes to enables the drift detector to provide more inputs to the readout circuit. In other embodiments, the drift detector 300 may not include the second HBL whereby the top planar electrode 316 is positioned adjacent the semiconductor layer 312.

An advantage of the disclosure is that radiation may impinge or strike the drift detector 300 in either a face-on illumination or edge-on illumination or both without affecting the measurements or readouts that are generated by the drift detector 300. Another improvement is that the disclosure is able to measure or readout parameters such as time, location and energy with respect to the contact between the illumination and the semiconductor layer based on a single contact between the illumination and the semiconductor layer 312.

As discussed above, in some embodiments, the drift microstrips are placed or located in a plane than the collecting electrodes. By having the drift microstrips and the collecting electrodes in separate planes, an improvement with respect to the efficiency of drift performance may be experienced over embodiments where the drift electrodes and the collecting electrodes are in the same plane due to a reduction of the likelihood of electrical leakage from the drift microstrip(s) to the collecting electrode(s). For embodiments where the drift microstrips and the collecting electrodes are in the same plane, larger gaps between the drifting microstrips and the collecting electrodes may be required which may reduce collection efficiency, increase drift time, and negatively affect the achievable spatial resolution. However, in some embodiments this may not be a concern whereby some embodiments of the disclosure may have the drift microstrips and the collecting electrodes in the same plane. Placement of the drift microstrips and the collecting electrodes on or in the same plane may also cause unnecessary trapped charge effects near the drift microstrips which may affect spatial resolution, energy resolution, sensitivity and/or collection efficiency. These negative effects may be reduced by placing the drift microstrips in a separate plane from the collecting electrodes such that the drift field or electric field influenced by the drift microstrips may be optimized or improved to only steer the charges towards the charge collecting electrodes.

To further optimize or improve the drift field to steer the charge towards the charge collecting electrode, the planar electrode at the top of the semiconductor can be designed to include the same drift microstrips running symmetrically with the drift electrodes on the substrate. To account for sending drift charge at the top surface of the semiconductor layer to the collecting electrode, a drift electrode directly atop the collecting electrode has to be designed to be slightly larger with a larger bias voltage compared to the other nearby drift microstrips. This embodiment is discussed in more detail with respect to FIG. 4.

Turning to FIG. 4, a side view of another embodiment of a large area semiconductor drift detector is shown. In the current embodiment, the drift detector 400 includes all of the components of the embodiment of FIG. 3 with the only difference being the design of the top planar electrode. Instead of the top planar electrode of FIG. 3, the drift detector 400 of FIG. 4 includes a second set of drift microstrips 402 including a set of narrow width microstrips 404 and a set of wider width drift microstrips 406. The wider width drift microstrips 406 may also be seen top layer contacts. While shown as being located atop the second HBL 314, the second set of microstrips 402 may be located within the second HBL 314. While the term wider is being used to distinguish between the different microstrips within the second set of microstrips, the microstrips within the second set of may be the same width with microstrips 406 having higher voltage with respect to the voltage of microstrips 404 adjacent to microstrips 406.

For both of the embodiments shown in FIGS. 3 and 4, the set of charge collecting electrodes 310, which may be dual end readouts, are placed near a bottom of the detector 300 or 400 proximate the first set of parallel drift strips, or microstrips 306, on both sides of the collecting electrode 310 (in a vertical alignment). In the embodiment of FIG. 4, the set of wider width drift microstrips 406 are located above each of the dual readout electrodes 310 in a vertical plane. These wider width drift microstrips are larger and have higher voltage values compared to the adjacent set of narrow width microstrips 404 whereby the set of wider width drift microstrips 406 are able to more strongly shape, influence or direct the electric field toward the collecting, or dual readout, electrodes 310. In some embodiments, the wider width drift microstrips are staggered with respect to the set of drift microstrips in a vertical plane.

In operation, x-ray or gamma radiation is directed at the semiconductor layer (in either a face-on illumination or an edge-on illumination or both). The radiation gets absorbed in the semiconductor layer and generates charges. This induces signal on top electrodes which triggers a calculation of the drift time. The drift microstrips, or electrodes, steer charges towards the collecting electrodes. The drift time is the time duration from the trigger point until the charges reach the collecting electrode. The drift time gives information about first coordination of the impact location. The collecting electrodes then supply or transmit the received charges or characteristics of the received charges to a readout circuit that processes the received charges. In charge division readout, two ends of the strip should be read simultaneously, and the ratio of the signals gives the location of impact along the strip direction (second coordination). Also, the ratio between the collecting electrode and the drift microstrips on the other side of the detector provide information relating to a third coordinate of impact location. One readout is sufficient for all the top microstrips to get the triggering for drift time calculation and signal ratio to get the depth of interaction. Depending on the application and the required spatial precision, it is possible to omit any of these coordinates and their corresponding implementation.

For example, if 3D positioning is being sensed using dual readout or resistive electrodes, the readout circuit receives two values or charges from each of the resistive electrodes. From the received charges, the readout circuit (or a processor associated with the readout circuit) can determine the position of contact between the radiation and the semiconductor layer along the microstrip directions by comparing the charge level/signal that is received from both ends. For example, if the resistive electrode has a length “x” (which also represents a length of the detector), if a readout from one end of the resistive electrode is three times more than the readout from the other end of the resistive electrode, it is understood that the location of impingement between the radiation and the semiconductor layer occurred one-quarter of the length “x” away from an edge of the detector or three-quarters of the length of “x” away from the opposite end of the detector.

Furthermore, when using the disclosure, photon detection and charge generation can occur in the vertical direction (face-on illumination) or the lateral direction (edge-on illumination), with the charge carriers (holes and/or electrons) drifting in a lateral direction within the drift detector.

In order to obtain 3D position sensing, a charge division readout including the resistive collecting electrodes is contemplated. Enablement of one embodiment of a large-area semiconductor drift detector using an a-Se position-sensitive microstrip detector with charge division is discussed in further detail below.

Testing of embodiments of the disclosure was performed by developing a 3D model with a finite element method in multiphysics software in order to reduce the innovation to practice. For this testing, an electric field and potential were simulated for a cross-section of the detectors 300 or 400.

With the embodiment shown in FIG. 4, the width of each of the set of first or second microstrips 306 or 404 was chosen to be similar to the width of the collecting electrodes 310 in the drift detector 400, however, they may have different widths. In order to simulate its electric field in bulk with the drift structure, a line orthogonal to a direction of the strips and in the middle of the selenium semiconductor layer along which to plot the electric field was considered. In a conventional microstrip detector (with no drift microstrips), the spatial resolution relies on the quantity, or number, of collecting electrodes. In order to increase the spatial resolution and energy resolution without increasing the number of collecting electrodes, the drift detector structure of Figures and 4 were used.

Utilizing resistive dual readout electrodes 310 further reduces the number of readout channels and improves the energy resolution of the large-area semiconductor drift detector with a-Se as the semiconductor layer. It is understood that other semiconductor materials (such as those listed above) produce similar or expected results, however, only a-Se was tested. Moreover, when in face-on illumination geometry, by reducing the number of readout channels or collection electrodes 310, the stacking of multiple a-Se drift detectors (in order to increase sensitivity to higher energy radiation) is possible, thereby providing a cost-effective alternative for gamma photons detection applications. When used in edge-on illumination, the disclosure can be seen as a cost-effective alternative for small area detection applications that require low dose irradiation and high detection efficiency.

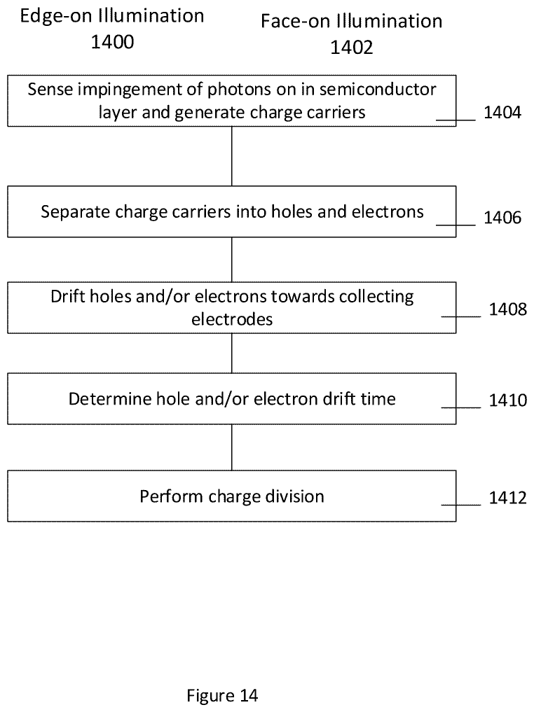

Turning to FIG. 14, a flowchart showing a method of using a large-area semiconductor drift detector is shown. As discussed above, illumination of the drift detector may either be in an edge-on illumination or a face-on illumination. Edge-on illumination 1400 occurs when the photons (or radiation) impinges the drift detector from the edge side of the detector leading to a higher detection efficiency. Face-on illumination 1402 occurs when photons (or radiation) impinges the detector from the top or bottom of the drift detector (or perpendicular to the surface of the microstrips). Face-on illumination is beneficial for use with large-area applications.

Initially, regardless of which type of illumination is being used, the drift detector senses the impingement of photons within the semiconductor layer which results in the photons being absorbed in a bulk of the detector thereby creating charge carriers (1404). Due to an electric field that is created and shaped by the size and location of the drift microstrips, electrons and holes are separated and move in different directions (1406).

An electric field is then generated within the drift detector to drift charges towards the collecting electrodes (1408). In one embodiment, when using a-Se, electrons are drifted or directed toward the nearest top contact or microstrip which is directly above and adjacent the impact location (place of contact between a photon and the semiconductor layer) as electrons travel, at most, the thickness of the detector. Holes are drifted or directed toward the collecting electrode located at a center of the detector cell so that the holes travel, at most, half of the cell length. In further embodiments, depending on the semiconductor material, the holes may be drifted towards the top contact or the second set of microstrips while the electrons are drifted towards the collecting electrodes.

If the embodiment of FIG. 4 is being used, the presence of the parallel drift microstrips 306 and 402 on both sides of the detector provide a uniform electric field across the charge drift length toward a centre of the detector cell. If the embodiment of FIG. 3 is being used, the presence of a whole planar electrode on one side of the semiconductor layer and the drift microstrips and the collecting electrodes on the other side of the semiconductor simplifies the fabrication process and reading of the trigger signal. It is understood that the embodiment of FIG. 3 or the embodiment of FIG. 4 may be used for edge-on illumination, face-on illumination or both.

The movement of the electrons creates or generates a signal which triggers the recording of hole drift time toward the collecting electrode(s) (1410). The signal ratio of the top contact and bottom collecting electrodes may be used to obtain the vertical location of the impact location. Depending on the semiconductor material, either the hole drift time or the electron drift time provides the location of impact along the length of the detector.

For charge division readout (1412), the holes that arrive at the collecting electrode experience charge division due to the resistivity of the electrode. Both ends of the dual readouts electrodes are read simultaneously, and the ratio of these two signals provides the location of impact along the width of the detector (i.e. along the collecting electrode direction) such as discussed above.

With respect to the large-area semiconductor drift detector of the disclosure, in one embodiment, the drifting microstrips are embedded in the structure and are not in the same plane as the collecting electrodes. This embedded structure reduces the charge injection and trapping near the drift microstrips.

Turning back to FIG. 4, the model that was generated was an entire cell with a half-cell on each side simulated with microstrips at the top. In other words, as can be seen in FIG. 4, the detector 400 includes a central detector cell 318 with a half detector cell (ending with the wider width microstrip 406) adjacent the detector cell 318 on each side. Thirteen drifting microstrips 306 were used per detector cell 318 for the bottom (section between the semiconductor layer and the substrate) of the detector with twelve of them having a matching or corresponding parallel strip 404 on the top portion of the detector with a 250 V reduction step in their values along the drift direction staring from 3500 V at edges of a cell to the center of the cell. Although thirteen microstrips were chosen for this testing embodiment, any different numbers of microstrips can be used depending on the application and required spatial and energy resolutions. The geometry properties for the testing embodiment are listed in Table 1. As would be understood by one skilled in the art, the voltages noted above, the number of microstrips chosen, the number of devices stacked and device dimensions shown in the table are just one particular solution for one particular application and there would be many combinations possible with a-Se and/or other different large area semiconductor material layers that could be employed for different applications at different energies.

TABLE 1
COMSOL Model - Geometry Parameters

| Parameter | Value | |
|---|---|---|
| Detector size | 8 mm × 8 mm | |
| Detector cell size | 3.9 mm × 8 mm | |
| Drift/collecting microstrips size | 100 μm × 8 mm | |
| Top contact microstrips size | 200 μm × 8 mm | |
| Gap between drift microstrips | 50 | μm |
| a-Se thickness | 500 | μm |
| Microstrips thickness | 100 | nm |
| HBL thickness | 2 | μm |
| EBL thickness | 1 | μm |
| Substrate thickness | 40 | μm |

In experiments, the electric field and potential distribution for an a-Se detector with a set three readout, or collecting electrodes, was used for the simulation (see FIGS. 3 and 4). A focus was placed on the middle collecting electrode (part of detector cell 318), and the two distal end collecting electrodes were implemented to consider their effect on the field shaping of the detector cell 318.

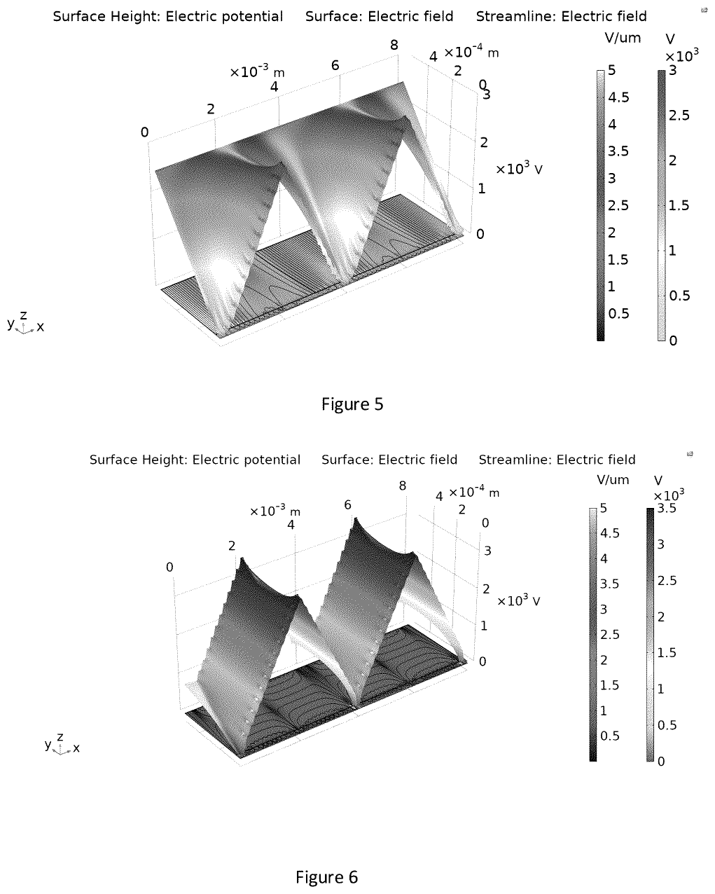

The electric potential and field simulation results for the embodiment of FIG. 3 and FIG. 4 are shown in FIGS. 5 and 6, respectively. For FIG. 5, a drift detector with the design of FIG. 3 was used for this simulation as the planar top contact creates an electric potential valley whereby holes generated in bulk drift toward the collecting electrodes. However, in this embodiment, further away from the collecting electrodes, the probability of holes moving directly toward one of the microstrips and getting trapped is higher according to the electric field streamlines.

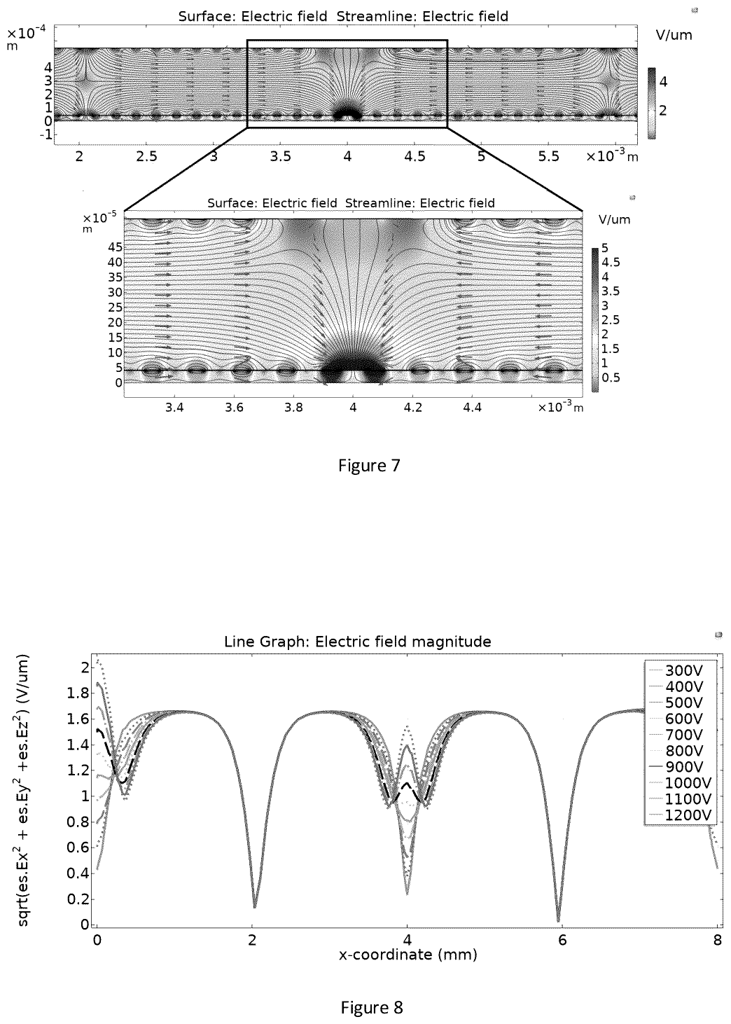

To improve operation with respect to this issue, a second embodiment, such as the one described with respect to FIG. 4 may be used. In the embodiment of FIG. 4, drift microstrips were placed on both sides of the detector to direct or drift holes smoothly toward the center of the detector cell. The top contact (or wider width microstrips) at the center of the detector cell 318, with a higher voltage than its adjacent narrower width microstrips, is responsible for drifting the holes toward the collecting electrode for the cell 318. Therefore, parallel microstrips on both sides of the semiconductor layer and top contacts 406 at the center of the detector cell 318 help reduce the probability of charges being trapped between adjacent strips and ensure a uniform electric field in the drift area such as schematically shown in FIG. 7 which shows electric field magnitude and direction inside the detector with a top contact voltage of 700V.

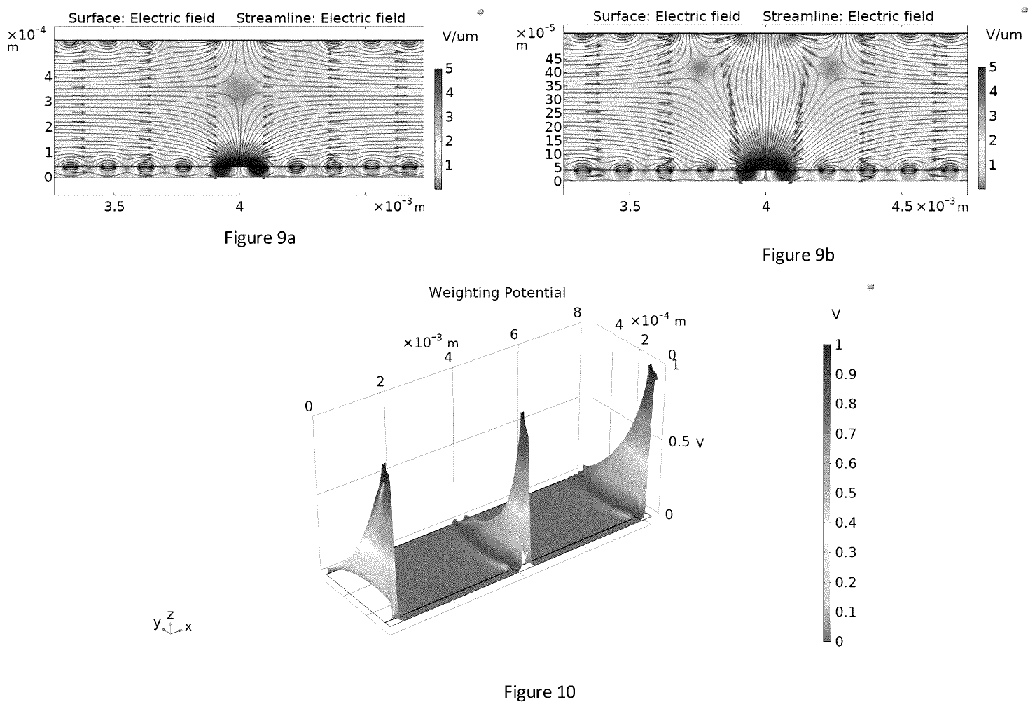

A parametric simulation was carried out to choose a voltage value for the wider width microstrip 406 and the result illustrated in FIG. 8. It can be see that for 800 V, there are more uniform fields near the collecting electrode. For voltages below 800 V, the field is not strong enough to drift all charges toward the collecting electrode. For voltages above 800 V, two electric field valleys are created near the middle of the detector thickness (as shown in FIGS. 9a and 9b), which increases the chance of charges being trapped in those areas. FIG. 9a shows an electric field streamline for V_{B}=400V and FIG. 9n shows an electric field streamline for V_{B}=1200V.

Embodiments with a uniform drift field enable a high spatial resolution and also achieve unipolar charge sensing for carriers with higher mobility. Thus, it reduces the contribution of slow carriers on the signal resulting in higher temporal and energy resolution. The weighting potential is simulated to verify the unipolar charge sensitivity as shown in FIG. 10 which is a graph showing weighting potential across the drift detector with collecting electrodes biased at 1V and the others at zero.

For a conventional planar electrode detector without drift microstrips, the weighting potential may be a linear function calculated based on the Shockely-Ramo theorem by assuming the potential of the anode is 1. Here, the potential of collecting electrodes was set to 1V, and other electrodes were grounded. The weighting potential distribution illustrated in FIG. 10 drops to zero in the vicinity of the collecting electrodes along the drift direction, verifying that no charge is induced on the collecting electrodes due to the movement of slow charge carriers.

To readout the signal from the large-area semiconductor drift detector, the detector may be connected to an integration mode or a photon counting readout circuit. An integration mode circuit is simpler to implement, however, it does not provide energy resolution and cannot help discriminate the energy of the radiation impinging on the detector. A photon counting circuit is able to provide both energy information along with timing of photon absorption to obtain of determine an accurate positional location of radiation absorption. Both types of integration and photon counting readout circuits can work with resistive and metal electrodes.

With respect to design and fabrication of the disclosure for testing purposes, a resistive microstrip or collection electrode readout was adapted to investigate the feasibility and the longitudinal position linearity for a radiation detector with an a-Se semiconductor layer.

In one embodiment of fabrication, the bottom or collecting electrode was initially defined. To employ charge division readout, in one embodiment, indium tin oxide (ITO) was used (although others are contemplated) as a resistive microstrip or collecting electrode at the bottom of the detector (between the semiconductor layer and the substrate layer. The ITO was deposited on the substrate layer using a shadow mask through E-beam evaporation although other methods of deposition such as sputtering and/or physical vapor deposition are contemplated. For this specific embodiment, a width, length, and thickness of each collecting electrode was selected to be 200 μm, 19 mm, and 100 nm, respectively. These dimensions were chosen to have a collecting electrode with a resistance of approximately 242 kΩ (12.7 kΩ/mm). Then, a stabilized a-Se photoconductor was thermally evaporated on the collecting electrodes to fabricate the semiconductor layer.

In one specific embodiment, a hole blocking layer may be required between the semiconductor and the top planar contact (or the second set of microstrips). For this hole blocking layer, a Cs-doped and As-stabilized a-Se was used and thermally evaporated on the a-Se semiconductor layer to lower the dark current. Other similar materials may be contemplated for the hole blocking layer. A thin layer of chromium (Cr) was then placed atop the hole blocking layer through E-beam evaporation. In other embodiment, there are multiple alternatives to achieve adequate hole blocking properties including using alternate materials for blocking layers such as, but not limited to, SU-8, polystyrene, bi-layers of SU-8 and Cs doped a-Se, and/or PTCBI. It is noted that any of these material may be considered for hole blocking layers in either drift detector embodiments.

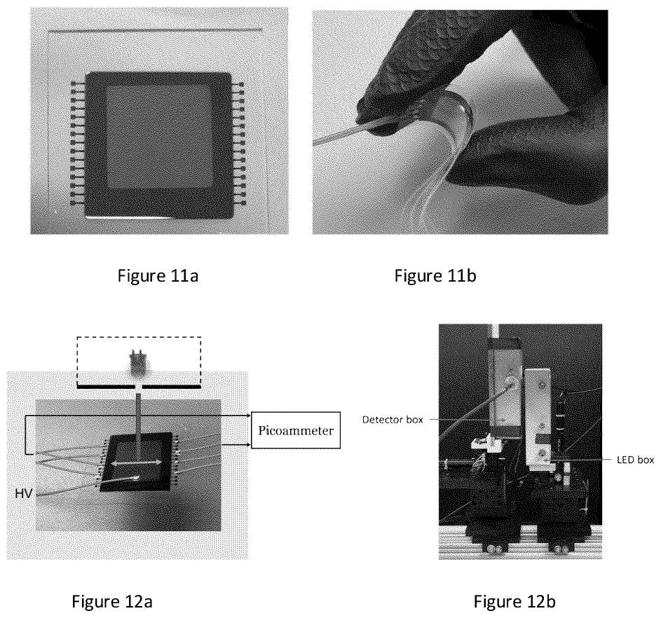

Two devices were fabricated on two different substrates: glass and polyethylene terephthalate (PET), which are shown in FIGS. 11a and 11b respectively. There are many advantages to using a large-area flexible detector, including cost-effectiveness, robustness, and its ability to be fitted into curved structures to avoid or reduce detector tiling around the body and to be utilized in mobile systems. Therefore, the disclosure may be used within a flexible detector.

To investigate, position detection linearity, the setup shown in FIGS. 12a and 12b were used. The setup of FIG. 12a shows the model while the setup of FIG. 12b shows the detector assembled on motorized stages.

A blue LED with a wavelength of 470 nm followed by a metal collimator with an aperture of 400 μm was used to create a beam with a focal spot of approximately 1 mm on the detector. Both the LED and detector boxes were mounted on motorized stages (FIG. 12b) to control the lateral and vertical positions. Due to the sensitivity of the detector readouts, only the light source was used to sweep across the detector. A high voltage (HV) of 250 V was applied to the top electrode to create an electric field of 10 V/μ across the detector. A dual-channel picoammeter was used to measure the current at both ends of the ITO electrodes (or resistive electrodes). Due to a slight mismatch between both channels, a fixed current was passed through the resistive collecting electrode from one channel to the other one. The dark current was divided between the two channels. Hence, the total read current for each channel is

$${I}_{Ch 1} = {I}_{Ph 1} + {I}_{Dark} / 2 + {I}_{R} , \qquad ( 1 )$$

$${I}_{Ch 2} = {I}_{Ph 2} + {I}_{Dark} / 2 - {I}_{R} , \qquad ( 2 )$$

where I_{Ph1} and I_{Ph2} are the photocurrents read by channel 1 and channel 2, respectively. I_{R} is the constant current due to the mismatch between the channels, and I_{Dark} is the total dark current read by only one end of the electrode connected to the picoammeter. From Equations (1) and (2), dark current and mismatch current can be obtained in dark condition, i.e., I_{Ph1}=I_{Ph2}=0, as follow

$${I}_{Dark} = {I}_{Ch 1} + {I}_{Ch 2} , \qquad ( 3 )$$

$${I}_{R} = ( {I}_{Ch 1} - {I}_{Ch 2} ) / 2. \qquad ( 4 )$$

Using the dark current and photocurrent measurements, one can show via the charge division method that the location of the incident photon relative to channel 2 is:

$$X = \frac{{I}_{Ph 1}}{{I}_{Ph 1} + {I}_{Ph 2}} L , \qquad ( 5 )$$

where L is the length of the microstrip.

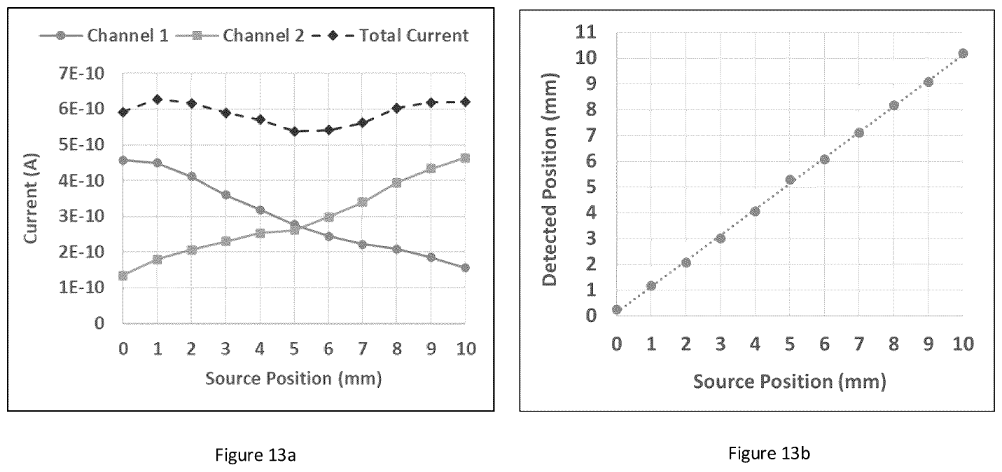

The results from the experiments were as follows and as shown in FIGS. 13a and 13b. FIG. 13a shows the photocurrents read from the two ends of a single electrode after dark current correction versus the position of the light source and FIG. 13b shows detected position from the charge division equation along the electrode versus the physical location of the light source.

After 2 hours of rest, the total dark current was 20 pA/mm². For photocurrent measurement, the LED stage was swept over the detector with 1 mm steps from the beginning of the active area shown in FIG. 13b. The active area here is the overlap of Cr thin film and the electrode. Before each photocurrent measurement, a dark measurement was done to update the dark current value, affected by radiation, and the mismatch current using Equation (2). These values were used to offset the read current from channels to extract the photocurrents (I_{Ph1},I_{Ph2}). The total photocurrent and photocurrent of each channel are plotted in FIG. 13a. The total current fluctuates in the middle but stays within the same range for the whole length of the active area. This fluctuation at the middle is the result of signal attenuation since most of the charges generated at the middle have to travel a longer distance in total.

The relative position of incident light was calculated based on equation 5. Then, this relative position was normalized to have position X=0 referenced to the beginning of the active area, which is 10 mm long. FIG. 13b shows that the detected position is linear with respect to the position of the light source. Therefore this structure has the potential to be employed for extracting the exact position of absorbed photons.

Applicants reserve the right to pursue any embodiments or sub-embodiments disclosed in this application; to claim any part, portion, element and/or combination thereof of the disclosed embodiments, including the right to disclaim any part, portion, element and/or combination thereof of the disclosed embodiments; or to replace any part, portion, element and/or combination thereof of the disclosed embodiments.

The above-described embodiments are intended to be examples only. Alterations, modifications and variations can be effected to the particular embodiments by those of skill in the art without departing from the scope, which is defined solely by the claims appended hereto.

What is claimed is:

1. A large-area semiconductor drift detector comprising:
a substrate layer;
a semiconductor layer;
a set of drift microstrips positioned between the substrate layer and the semiconductor layer; and
a set of collecting electrodes positioned between the substrate layer and the semiconductor layer and in a different plane than the set of drift microstrips;
wherein the set of drift microstrips shape an electric field and direct charges within the drift detector towards the set of collecting electrodes.

2. The large-area semiconductor drift detector of claim 1 further comprising:
a top planar electrode located on a side of the semiconductor layer opposite the set of drift microstrips and the set of collecting electrodes.

3. The large-area semiconductor drift detector of claim 1 further comprising:
a top set of drift microstrips located on a side of the semiconductor layer opposite the set of drift microstrips and the set of collecting electrodes.

4. The large-area semiconductor drift detector of claim 3 wherein the top set of drift microstrips comprises:
a set of wide width drift microstrips; and
a set of narrow width drift microstrips.

5. The large-area semiconductor drift detector of claim 1 wherein the set of drift microstrips and the set of collecting microstrips are staggered with respect to each other in a vertical plane.

6. The large-area semiconductor drift detector of claim 1 wherein a width of each of the set of drift microstrips is a same as a width of each of the set of collecting electrodes.

7. The large-area semiconductor drift detector of claim 3 wherein the set of wide width drift microstrips are in a same vertical plane as each of set of collecting electrodes.

8. The large-area semiconductor drift detector of claim 7 wherein a width of each of the set of wide width drift microstrips is larger than a width of each of the set of collecting electrodes.

9. The large-area semiconductor drift detector of claim 8 wherein a width of each of the set of narrow width drift microstrips is a same as a width of each of the set of collecting electrodes.

10. The large-area semiconductor drift detector of claim 1 wherein the semiconductor layer comprises amorphous selenium; lead-based organic perovskites, bismuth-based organic perovskites, lead oxide, bismuth iodide, mercuric iodide, quantum dot based semiconductors, thallium bromide and amorphous silicon.

11. The large-area semiconductor drift detector of claim 1 wherein the set of collecting electrodes are a set of dual readout resistive electrodes or a set of single readout metal collecting electrodes.

12. A method of large-area semiconductor drift detector operation comprising:
receiving at least one of face-on or edge-on illumination;
directing, via a set of drift microstrips, electron and hole charges towards a set of collecting electrodes; and
determining a position of impingement of illumination against the drift detector;
wherein the set of drift microstrips and the set of collecting electrodes are in different planes with respect to each other.
